(19) United States
(12) Patent Application Publication
(10) Pub. No.: US 2006/0063027 A1
(43) Pub. Date: Mar. 23, 2006

(54) Organic electroluminescent element

(75) Inventors: Horst Vestweber, Gilserberg (DE); Anja Gerhard, Veitschochheim (DE); Philipp Stossel, Frankfurt (DE); Hubert Spreitzer, Viernheim (DE)

Correspondence Address: CONNOLLY BOVE LODGE & HUTZ, LLP, P O BOX 2207, WILMINGTON, DE, 19899, US

(73) Assignee: Covion Organic Semiconductors GmbH, Frankfurt am Main (DE)

(21) Appl. No.: 10/540,461

(22) PCT Filed: Dec. 9, 2003
(86) PCT No.: PCT/EP03/13927

§ 371 Date: Jul. 21, 2005

(30) Foreign Application Priority Data
Dec. 23, 2002 (DE) 102 61 545.4

(51) Int. Cl. H01L 51/54; H05B 33/14; C09K 11/06

(52) U.S. Cl. 428/690; 428/917; 313/504; 252/301.16; 564/305; 313/506

(57) ABSTRACT

The present invention relates to the improvement of organic electroluminescent devices, which is characterized in that the emitting layer (EML) consists of a mixture of two substances, one having hole-conducting properties and the other having light-emitting properties, and at least one of these compounds containing a spiro-9,9′-bifluorene unit.

The present invention relates to a novel design principle for organic electroluminescent elements and to their use in displays based thereon.

In a series of different types of application which can be classed within the electronics industry in the widest sense, the use of organic semiconductors as functional components (=functional materials) has been reality for some time or is expected in the near future. For instance, light-sensitive organic materials (e.g. phthalocyanines) and charge transport materials on an organic basis (generally hole transporters based on triarylamine) have already found use in copying machines.

The use of specific semiconductive organic compounds, some of which are also capable of emission of light in the visible spectral region, is just starting to be introduced onto the market, for example in organic electroluminescent devices. Their individual constituents, the organic light-emitting diodes (OLEDs), have a very wide spectrum of application as:
1. white or colored backlighting for monochrome or multicolor display elements (for example in pocket calculators, mobile telephones and other portable applications),
2. large-surface area displays (for example traffic signs, billboards and other applications),
3. illumination elements in all colors and forms,
4. monochrome or full-color passive matrix displays for portable applications (for example mobile telephones, PDAs, camcorders and other applications),
5. full-color, large-surface area, high-resolution active matrix displays for a wide variety of applications (for example mobile telephones, PDAs, laptops, televisions and other applications).

In these applications, the development is in some parts already very far advanced, but there is nevertheless still a great need for technical improvements.

Relatively simple devices comprising OLEDs have already been introduced onto the market, as demonstrated by the car radios having organic displays from Pioneer. However, there are still considerable problems which are in need of urgent improvement:
1. In particular, the OPERATIVE LIFETIME of OLEDs, in particular for a BLUE EMISSION, is still very low, so that only simple applications can be commercially realized to date. Sanyo have reported lifetimes for application-relevant brightnesses of blue OLEDs in the range of approx. 3000 h. There are also similar values for materials from Kodak.
2. This relatively short lifetime also results in a consequent problem: specifically for FULL-COLOR applications (“full-color-displays”), i.e. displays which have no segmentations, but rather can represent all colors over the whole surface, it is particularly serious when the colors age here at different rates, as is currently the case. Typical lifetimes for green and red OLEDs are about 30 000 and 20 000 h respectively. This leads to the result that, even before the end of the abovementioned lifetime (which is generally defined by a fall to 50% of the starting brightness), there is a distinct shift in the white point, i.e. the trueness of color of the representation in the display becomes very poor. In order to avoid this, some display manufacturers define the lifetime as the 70% or 90% lifetime, (i.e. the fall in the starting brightness to 70% and 90% of the starting value respectively). However, this leads to the lifetime becomine even shorter, i.e. in the range of a few hundred hours for BLUE OLEDs.
3. In order to compensate for the decrease in the brightness, especially in the blue, the required operating current can be raised. However, such a control mode is significantly more complicated and expensive.
4. The efficiencies of OLEDs, specifically in the blue; are already quite good, but here too, specifically for portable applications, improvements are of course still desired.
5. The color coordinates of OLEDs, specifically in the blue, are already quite good, but here too improvements are of course still desired. Particularly the combination of good color coordinates with high efficiency still has to be improved.
6. The aging processes are generally accompanied by a rise in the voltage. This effect makes voltage-driven organic electroluminescent devices, for example displays or display elements, difficult or impossible. However, a current-driven control mode is more complicated and expensive in this case too.
7. The required operating voltage has been reduced in the last few years, but has to be reduced still further in order to improve the power efficiency. This is of great significance specifically for portable applications.
8. The required operating current has likewise been reduced in the last few years, but has to be reduced still further in order to improve the power efficiency. This is particularly important specifically for portable applications.

The reasons mentioned above under 1 to 8 make improvements in the production of OLEDs very desirable.

The general structure of organic electroluminescent devices is described, for example, in U.S. Pat. No. 4,539,507 and U.S. Pat. No. 5,151,629.

Typically, an organic electroluminescent device consists of a plurality of layers which are preferably applied one on top of another by means of vacuum methods. These layers are specifically:
1. A carrier plate=substrate (typically glass or plastics films).
2. A transparent anode (typically indium tin oxide, ITO).
3. A hole injection layer (Hole Injection Layer=HIL): for example based on copper-phthalocyanine (CuPc) or conductive polymers such as polyaniline (PANI) or polythiophene derivatives (such as PEDOT).
4. One or more hole transport layers (Hole Transport Layer=HTL): typically based on triarylamine derivatives, for example 4,4′,4″-tris(N-1-naphthyl)-N-phenylamino)triphenylamine (NaphDATA) as the first layer and N,N′-di(naphth-1-yl)-N,N′-diphenylbenzidine (NPB) as the second hole transport layer.
5. An emission layer (Emission Layer=EML): this layer may coincide partly with the layers 4 or 6, but typically consists of host molecules, for example aluminum tris-8-hydroxyquinolinate (AlQ₃), doped with fluorescent dyes, for example N,N′-diphenylquinacridone (QA), or phosphorescent dyes, for example tris(phenylpyridyl)iridium (IrPPy).
6. An electron transport layer (Electron Transport Layer=ETL): for the most part based on aluminum tris-8-hydroxyquinolinate (AlQ₃).
7. An electron injection layer (Electron Injection Layer=EIL): this layer may coincide partly with layer 6, or a small portion of the cathode is treated specially or deposited specially.
8. A further electron injection layer (Electron Injection Layer=EIL): a thin layer consisting of a material having a high dielectric constant, for example LiF, Li₂O, BaF₂, MgO, NaF.
9. A cathode: here, generally metals, metal combinations or metal alloys having a low work function are used, for example Ca, Ba, Mg, Al, In, Mg/Ag.

This whole device is appropriately (depending on the application) structured, contacted and finally also hermetically sealed, since the lifetime of such devices generally shortens drastically in the presence of water and/or air. The same also applies to inverted structures in which the light is emitted from the cathode. In inverted OLEDs, the anode consists, for example, of Al/Ni/NiOx or Al/Pt/PtOx or other metal/metal oxide compounds which have a HOMO greater than 5 eV. The cathode consists of the same materials which have been described in point 8 and 9, with the difference that the metal, for example Ca, Ba, Mg, Al, In etc., is very thin and thus transparent. The layer thickness is below 50 nm, better below 30 nm, even better below 10 nm. A further transparent material is also applied to this transparent cathode, for example ITO (indium tin oxide), IZO (indium zinc oxide), etc.

Organic electroluminescent devices in which the emission layer consists of more than one substance have already been known for a long time:
EP-A-281381 describes OLEDs in which the EML consists of a host material which can transport holes and electrons, and a dopant which can emit light. One feature of this application is that the dopant is used in relatively small amounts (generally in the region of approx. 1%), and another is that the host material can (efficiently) transport both holes and electrons.
EP-A-610514 describes OLEDs which have small amounts (<19%, preferably <9%) of hole-transporting compounds in the EML. However, only very specific substance classes are permitted here for these compounds. The storage stability of such devices is relatively low.
EP-A-1162674 describes OLEDs in which the EML consists of an emitter doped with simultaneously a hole-transporting and an electron-transporting substance. A problem here from the technical point of view is that three compounds have to be applied here into one layer in a very precisely balanced mixing ratio. This is very difficult to realize technically with sufficient reproducibility, specifically in the predominant process (vacuum vapor deposition).
EP-A-1167488 describes OLEDs which have, as the EML, a specific combination of anthracene derivatives and aminodistyrylaryl compounds. A problem here from the technical point of view is that the compounds have a very high molecular weight, which leads in the predominant process and at the sublimation temperatures required therefor to the partial decomposition of the molecules and thus to worsening of the performance parameters.

It has now been found that, surprisingly, OLEDs which correspond to the inventive design principle detailed below have distinct improvements over the prior art.

The invention therefor provides an organic electroluminescent device which has at least one emitting layer (EML) which comprises a mixture of at least one hole conductor material and at least one emission material capable of emission, characterized in that at least one of the two materials comprises one or more spiro-9,9′-bifluorene units and the weight ratio of hole conductor material to emission material is from 1:99 to 99:1, preferably from 5:95 to 80:20, more preferably from 5:95 to 25:75.

In the context of the invention, capable of emission means that the substance, as a pure film in an OLED, has an emission in the range from 380 to 750 nm.

A preferred embodiment of the present invention is an organic electroluminescent device which has at least one emitting layer (EML) which consists of a mixture of at least one hole conductor material and at least one emission material capable of emission, the HOMO of the hole conductor material lying in the range from 4.8 to 5.8 eV (vs. vacuum) and the compound having at least one substituted or unsubstituted diarylamino group, preferably at least one triarylamino unit or a carbazole moiety, and the emission material capable of emission containing one or more spiro-9,9′-bifluorene units and the weight ratio of hole conductor material to emission material being from 1:99 to 99:1, preferably from 5:95 to 80:20, more preferably from 5:95 to 25:75.

A further preferred embodiment of the present invention is an organic electroluminescent device which has at least one emitting layer (EML) which comprises a mixture of at least one hole conductor material and at least one emission material capable of emission, the HOMO of the hole conductor material lying in the range from 4.8 to 5.8 eV (vs. vacuum) and the compound containing one or more spiro-9,9′-bifluorene units and at least one moiety selected from substituted or unsubstituted diarylamino, carbazole or thiophene units, and the emission material capable of emission being selected from the group of the metal complexes, stilbenamines, stilbenarylenes, fused aromatic or heteroaromatic systems, but also the phosphorescent heavy metal complexes, rhodamines, coumarins, substituted or unsubstituted hydroxyquinolinates of aluminum, zinc, gallium, bis(p-diarylaminostyryl)-arylenes, DPVBi (4,4′-bis(2,2-diphenylvinyl)biphenyl) and analogous compounds, anthracenes, naphthacenes, pentacenes, pyrenes, perylenes, rubrene, quinacridones, benzothiadiazole compounds, DCM (4-(dicyanomethylene)-2-methyl-6-(4-dimethylaminostyryl)-4H-pyran), DCJTB ([2-(1,1-dimethylethyl)-6-[2-(2,3,6,7-tetrahydro-1,1,7,7-tetramethyl-1H,5H-benzo[ij]quinolizin-9-yl)ethenyl]-4H-pyran-4-ylidene]propane-dinitrile), complexes of iridium, europium or platinum, and the weight ratio of hole conductor material to emission material being from 1:99 to 99:1, preferably from 5:95 to 80:20, more preferably from 5:95 to 25:75.

A further preferred embodiment of the present invention is an organic electroluminescent device which has at least one emitting layer (EML) which comprises a mixture of at least one hole conductor material and at least one emission material capable of emission, the HOMO of the hole conductor material lying in the range from 4.8 to 5.8 eV (vs. vacuum) and the compound containing one or more spiro-9,9′-bifluorene units and at least one moiety selected from substituted or unsubstituted diarylamino, carbazole or thiophene units, and the emission material capable of emission comprising at least one spiro-9,9′-bifluorene unit and the weight ratio of hole conductor material to emission material being from 1:99 to 99:1, preferably from 5:95 to 80:20, more preferably from 5:95 to 25:75.

The above-described devices have the following surprising advantages over the prior art:
1. The OPERATIVE LIFETIME becomes several times greater.
2. The efficiency of corresponding devices becomes higher in comparison to systems which do not follow the inventive design.
3. The color coordinates are better, i.e., specifically in the blue region, more saturated colors are achieved.

Details of the remarks made here can be found in the examples described below.

Preferred embodiments of the inventive OLEDs are those in which the glass transition temperature T_{g} of the particular hole conductor compound is greater than 90° C., preferably greater than 100° C., more preferably greater than 120° C.

It is a likewise preferred embodiment when the glass transition temperature T_{g} of the particular emission compound is greater than 100° C., preferably greater than 120° C., more preferably greater than 130° C.

It is particularly preferred when both the described high glass transition temperature of the hole conductor and that of the emission material are present simultaneously.

The preferred embodiments, described here, of the devices, as a result of the high glass transition temperatures, have an operative and also storage lifetime which have been increased further.

In the inventive OLEDs, the layer thickness of the EML is generally selected within the range from 5 to 150 nm, preferably within the range from 10 to 100 nm, more preferably in the range from 15 to 60 nm, most preferably in the range from 20 to 40 nm.
1. The color coordinates are better, and the optimal layer thickness is obtained for each desired color according to the resonance conditions d=λ/2n. For blue-emitting OLEDs, particularly good color coordinates are obtained when thin emission layers of 20-40 nm are selected. For green and red OLEDs, the layer thickness has to be adapted, i.e. increased, correspondingly.
2. The efficiency of corresponding devices is better. The optimal layer thickness ensures a balanced charge in the emission layer (emission film) and thus improves the efficiency. Especially the power efficiency is at its greatest in the case of thin emission layers of 20-40 nm.
3. The OPERATIVE LIFETIME is improved by several times in the case of optimal selection of the layer thickness, because a lower current is needed here with optimal color coordinates and efficiency.

Preferred hole conductor compounds are substituted or unsubstituted triarylamine derivatives, for example triphenylamine derivatives, but also corresponding dimeric or oligomeric compounds, i.e. compounds which contain two or more triarylamine subunits, and, as a subgroup, also corresponding carbazole derivatives, biscarbazole derivatives, or else oligocarbazole derivatives, likewise cis- or trans-indolocarbazole derivatives, additionally also thiophene, bisthiophene and oligothiophene derivatives, likewise pyrrol, bispyrrol and oligopyrrol derivatives; in selected cases, it is also possible that the triarylamino moiety is replaced by a hydrazone unit.

Particularly preferred hole conductor compounds are substituted or unsubstituted compounds of the formulae depicted below:

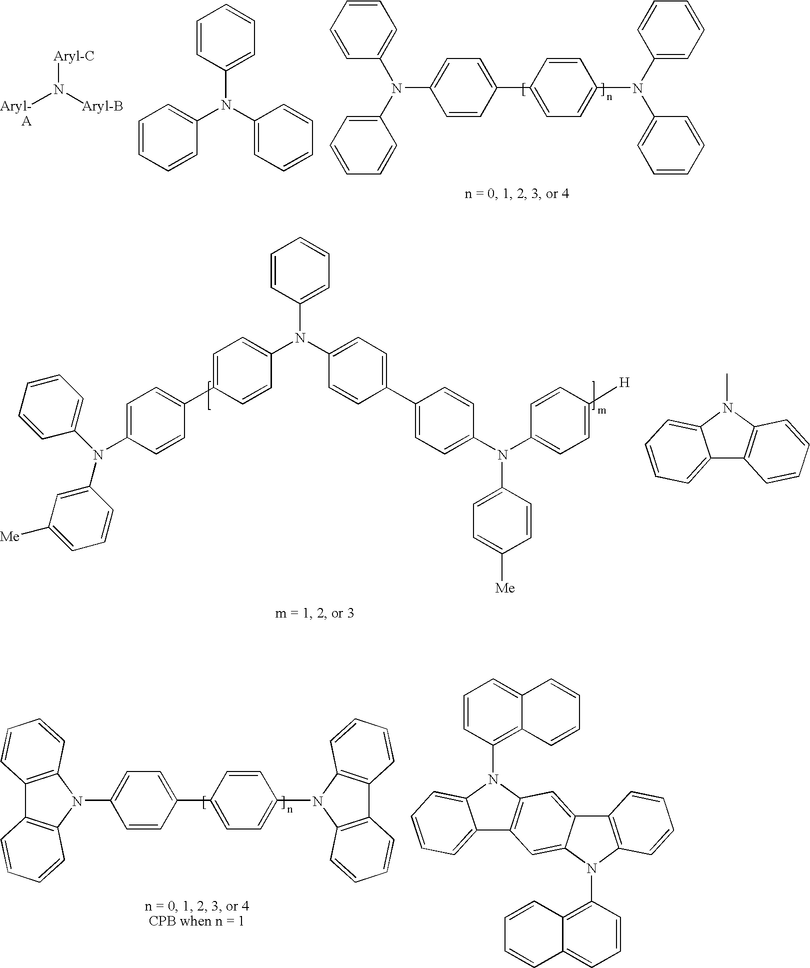

Aryl-A to Aryl-C represent aromatic or heteroaromatic cycles having from 4 to 40 carbon atoms.

Preferred hole conductor compounds are spiro-9,9′-bifluorene derivatives which bear from 1 to 6 substituents selected from substituted or unsubstituted diarylamino, carbazole, thiophene, bithiophene or oligothiophene moieties, but also compounds which contain, as substituents or instead of simple aryl groups, one or more substituted or unsubstituted spiro-9,9′-bifluorene derivatives. Preference is given to hole conductor materials which are present in the form of polymers and contain spiro-9,9′-bifluorene derivatives as a repeat unit, or spiro-9,9′-bifluorene derivatives whose M_{w} is not more than 10 000 g/mol; particular preference is given to hole conductor materials containing spiro-9,9′-bifluorene derivatives whose M_{w} is not more than 10 000 g/mol.

Particularly preferred hole conductor compounds are substituted or unsubstituted compounds of the formulae depicted below:

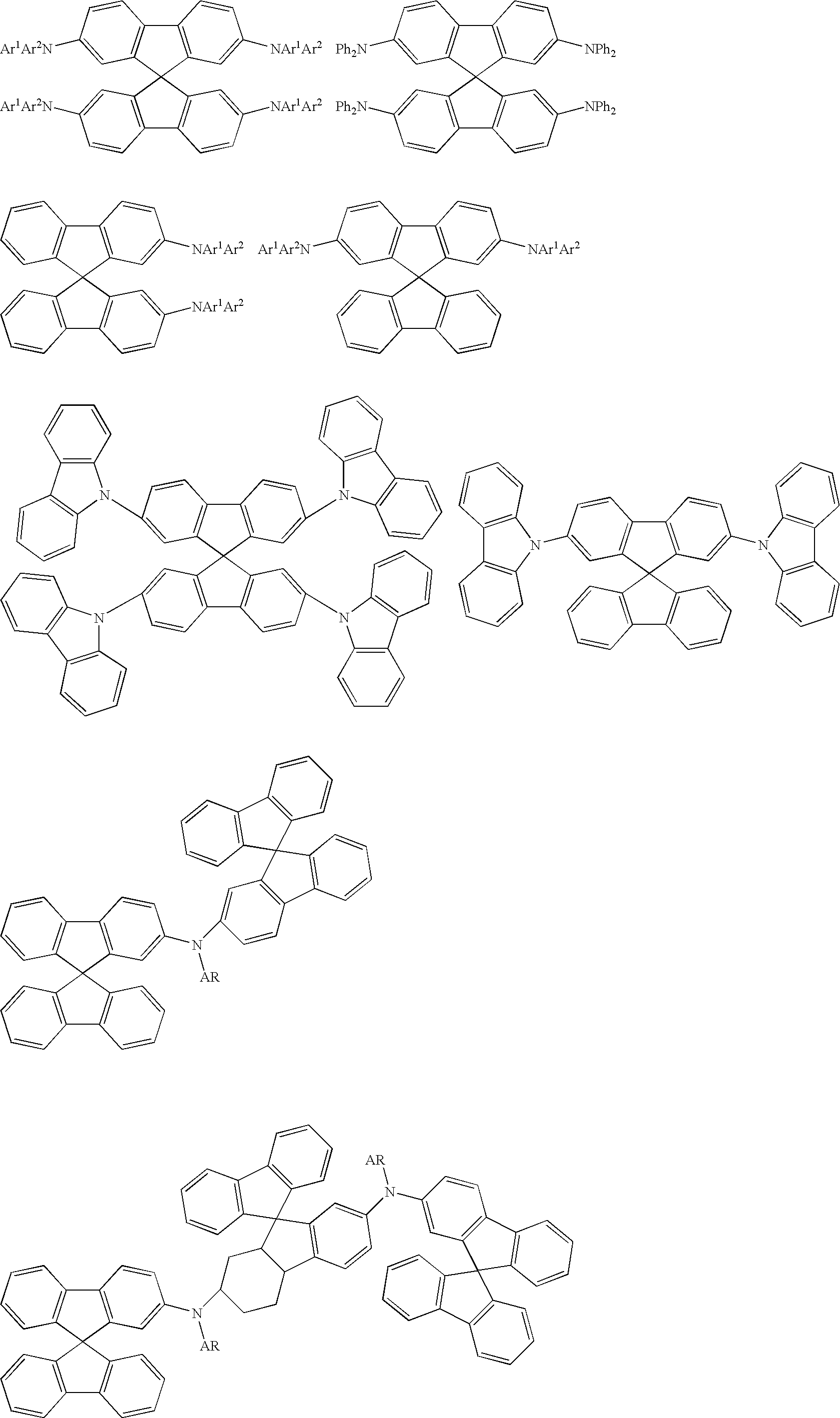

Ar¹, Ar² and AR represent here aromatic or heteroaromatic cycles having from 4 to 40 carbon atoms.

As already detailed above, preferred emission materials are metal-hydroxy-quinoline complexes, stilbenamines, stilbenarylenes, fused aromatic or heteroaromatic systems, but also phosphorescent heavy metal complexes, rhodamines, coumarins, for example substituted or unsubstituted hydroxyquinolinates of aluminum, zinc, gallium, bis(p-diarylaminostyryl)arylenes, DPVBi and analogous compounds, anthracenes, naphthacenes, pentacenes, pyrenes, perylenes, rubrene, quinacridone, benzothiadiazole compounds, DCM, DCJTB, complexes of iridium, europium or platinum.

Particularly preferred emission materials are substituted or unsubstituted compounds of the formulae depicted below: 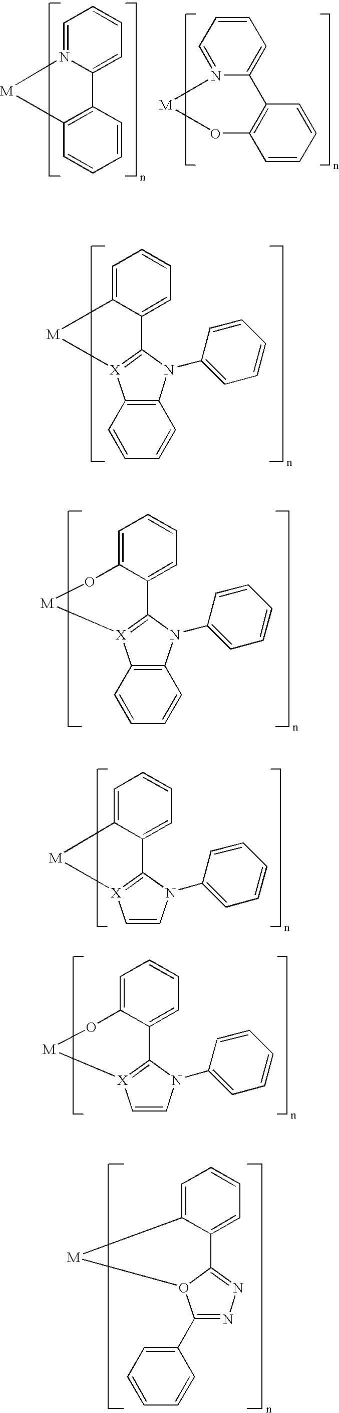
in which
n is the same or different and is 1, 2 or 3,
X is the same or different and represents the elements N, O or S,
M is the same or different and represents the elements Li, Al, Ga, In, Sc, Y, La, Cr, Mo, W, Fe, Ru, Co, Rh, Ir, Ni, Pd, Pt, Cu, Au, Zn, Ce, Pr, Nd, Pm, Sm, Eu, Gd, Tb, Dy, Ho, Er, Tm, Yb or Lu.

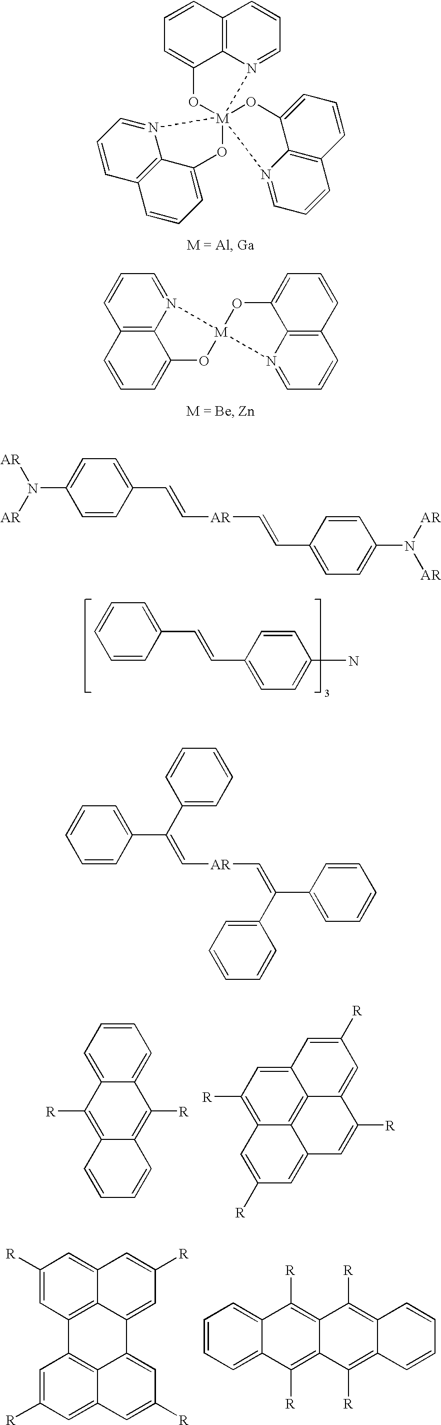

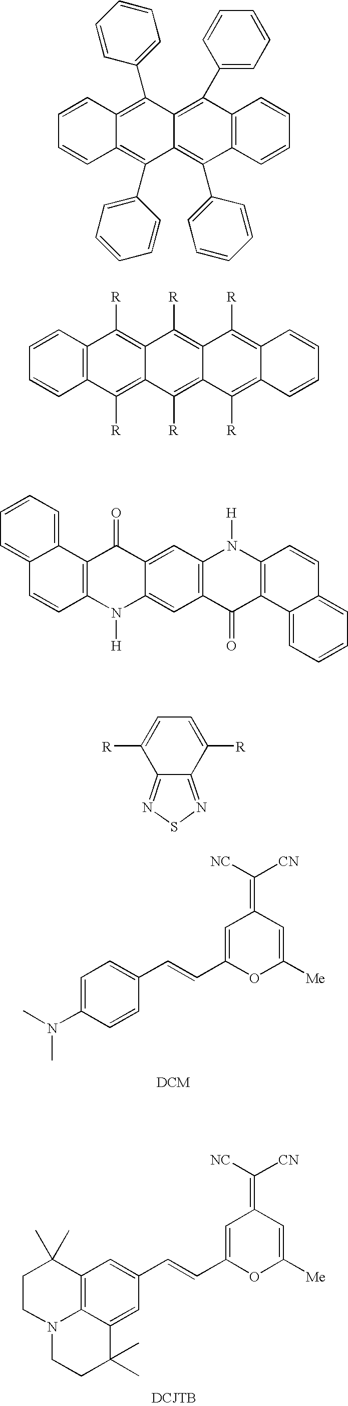

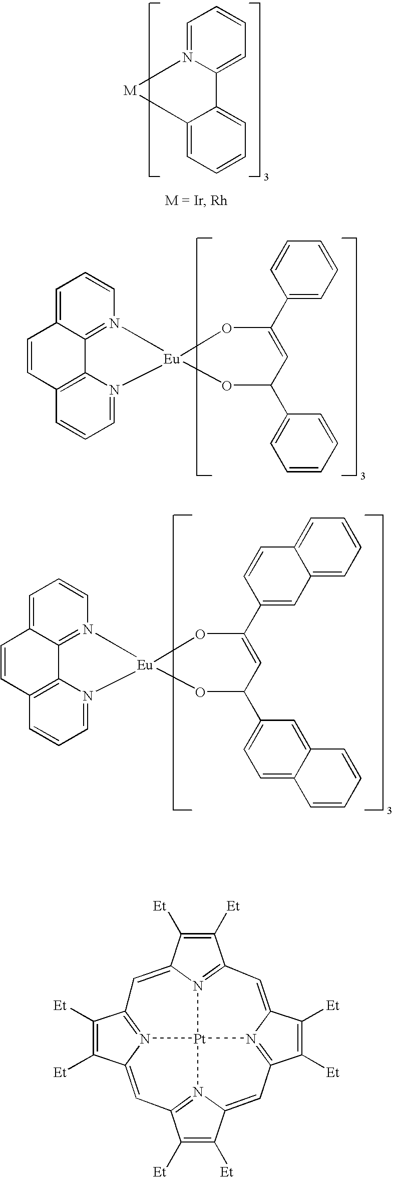

AR represents here aromatic or heteroaromatic cycles having from 4 to 40 carbon atoms; the substituents R are intended only to specify a preferred position of such groups and should not be regarded here as imposing any further restriction.

Preferred emission compounds are spiro-9,9′-bifluorene derivatives which bear from 1 to 6 substituents selected from substituted or unsubstituted arylenes, heteroarylenes, arylvinylenes or diarylvinylenes, but also arylenes, heteroarylenes or arylvinylenes which have one or more substituted or unsubstituted spiro-9,9′-bifluorene derivatives as substituents.

Particularly preferred emission compounds are substituted or unsubstituted compounds of the formulae depicted below:

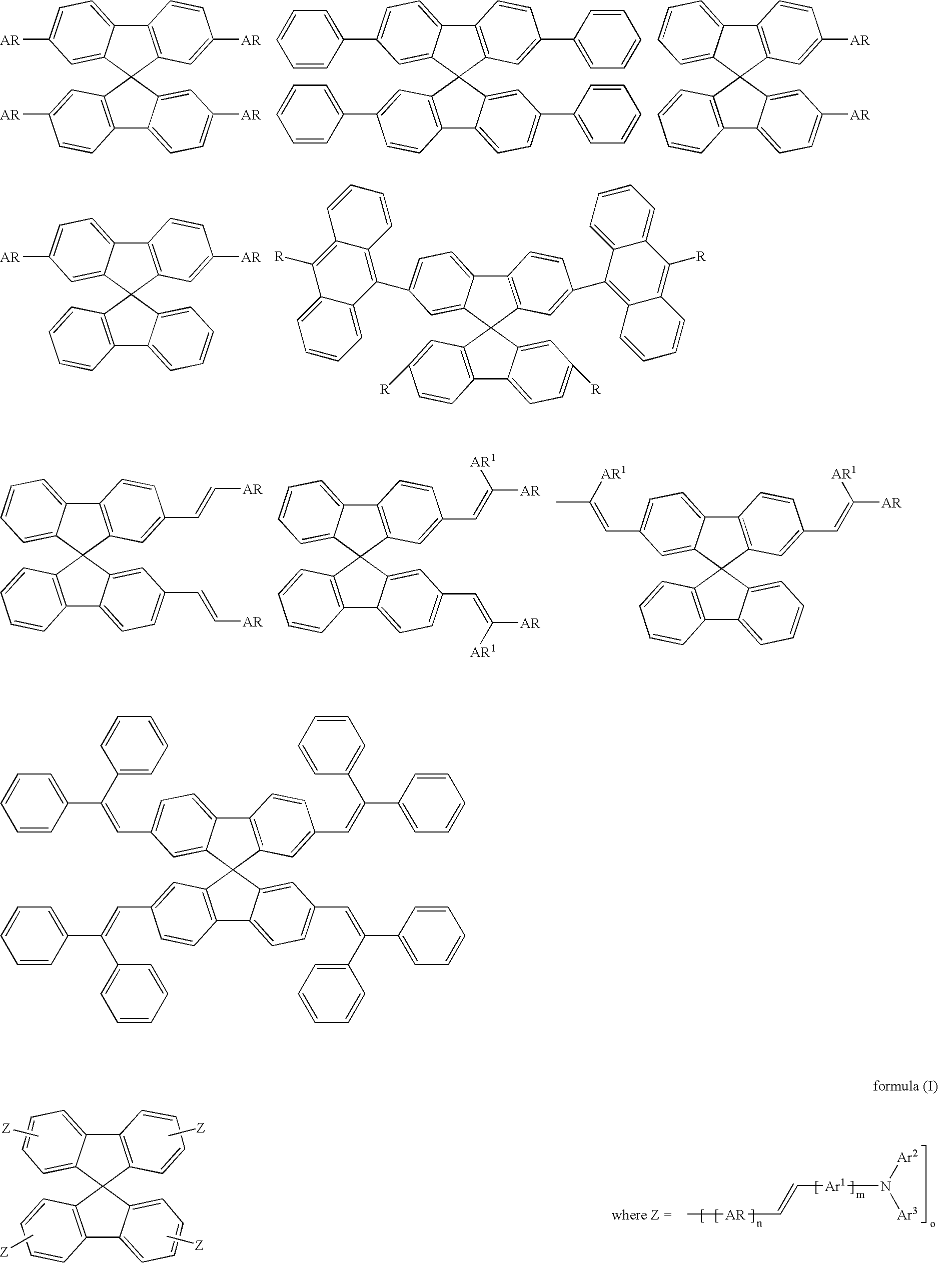

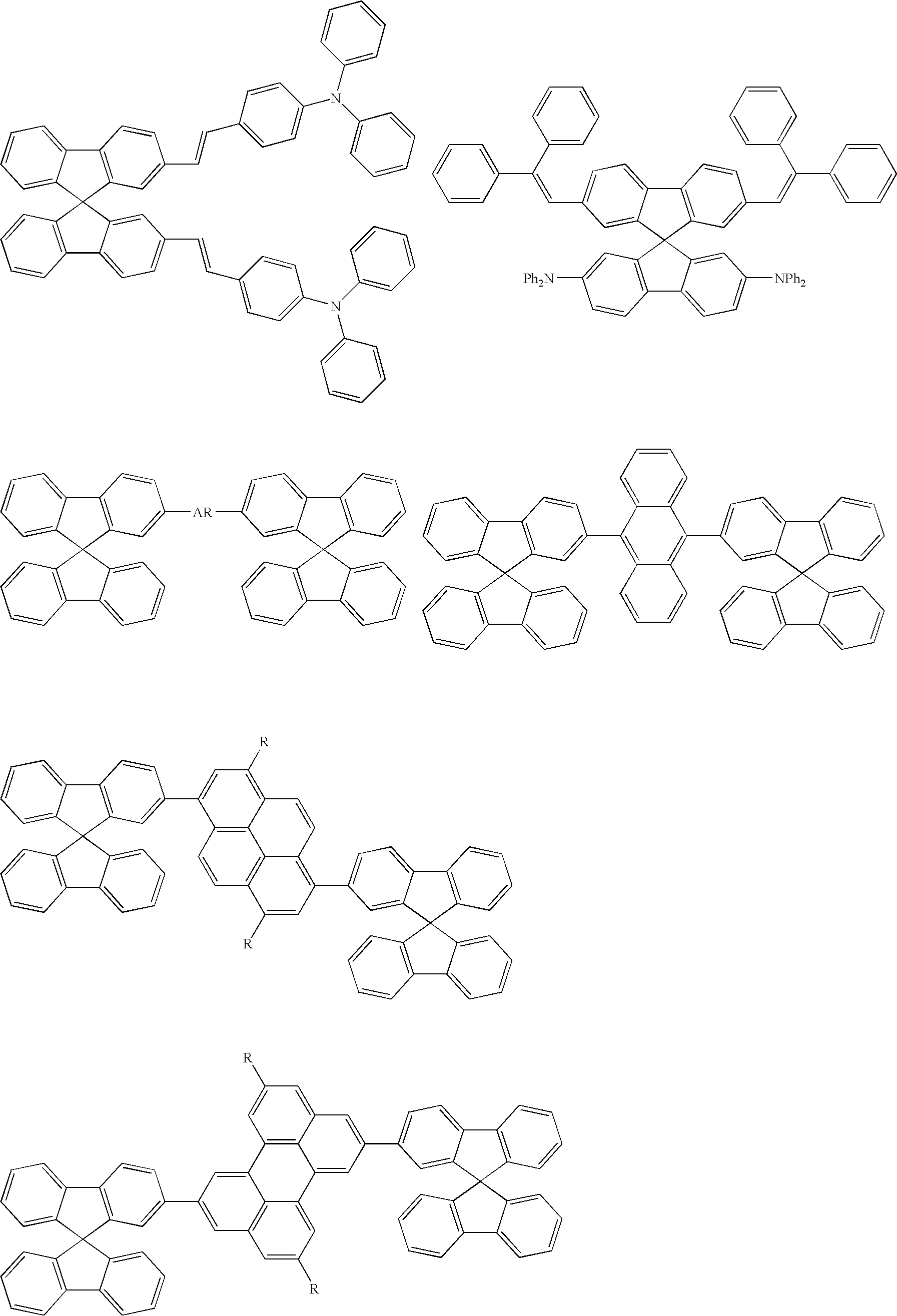

AR, Ar¹, Ar² and Ar³ represent here aromatic or heteroaromatic cycles having from 4 to 40 carbon atoms; n corresponds to 0, 1 or 2; m corresponds to 1 or 2, o corresponds to 1, 2, 3, 4, 5 or 6; the substituents R are only intended to specify a preferred position of such groups and should not be regarded here as imposing any further restriction. The Z radicals in formula (I) may be present multiply on one aromatic ring.

The compounds of the formula (I) are novel.

The invention therefore further provides compounds of the formula (I), 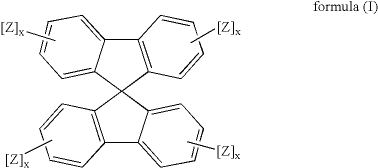
in which Z represents one or more groups of the formula 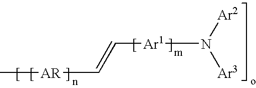
and in which the symbols and indices used are:
AR, Ar¹, Ar² and Ar³ are the same or different at each instance and are each aromatic or heteroaromatic cycles which have from 4 to 40 carbon atoms and may be substituted with substituents R¹ at the free positions;
n is the same or different at each instance and is 0, 1 or 2;
m is the same or different at each instance and is 1 or 2;
o is the same or different at each instance and is 1, 2, 3, 4, 5 or 6; where AR on Ar² or on Ar³ or on both, may be bonded in the form of a dendrimer;
x is the same or different at each instance and is 0, 1, 2, 3 or 4, with the proviso that the sum of all indices x is unequal to zero,
R¹ is the same or different at each instance and is a straight-chain, branched or cyclic alkyl or alkoxy chain which has from 1 to 22 carbon atoms and in which one or more nonadjacent carbon atoms may also be replaced by N—R², O, S, —CO—O—, O—CO—O, where one or more hydrogen atoms may also be replaced by fluorine, an aryl or aryloxy group which has from 5 to 40 carbon atoms and in which one or more carbon atoms may also be replaced by O, S or N and which may also be substituted by one or more nonaromatic R¹ radicals, or Cl, F, CN, N(R²)₂, B(R²)₂, where two or more R¹ radicals may also form an aliphatic or aromatic, mono- or polycyclic ring system with one another;
R² is the same or different at each instance and is H, a straight-chain, branched or cyclic alkyl chain which has from 1 to 22 carbon atoms and in which one or more nonadjacent carbon atoms may also be replaced by O, S, —CO—O—, O—CO—O, where one or more hydrogen atoms may also be replaced by fluorine, an aryl group which has from 5 to 40 carbon atoms and in which one or more carbon atoms may also be replaced by O, S or N and which may also be substituted by one or more nonaromatic R1 radicals.

Inventive electroluminescent devices may be prepared, for example, as follows:
1. ITO-coated substrate: the substrate used is preferably ITO-coated glass with a minimum level of or no ionic impurities, for example flat glass from Merck-Balzers or Akaii. However, it is also possible to use other ITO-coated transparent substrates, for example flexible plastics films or laminates. The ITO has to combine a maximum thermal conductivity with a high transparency. ITO layer thicknesses between 50 and 200 nm have been found to be particularly suitable. The ITO coating has to have maximum flatness, preferably with a roughness below 2 nm. The substrates are initially precleaned with 4% Dekonex in deionized water. Afterward, the ITO-coated substrate is either treated with ozone for at least 10 minutes or with oxygen plasma for a few minutes, or irradiated with an excimer lamp for a short time.
2. Hole injection layer (Hole Injection Layer=HIL): the HIL used is either a polymer or a low molecular weight substance. Particularly suitable polymers are polyaniline (PANI) or polythiophene (PEDOT) and derivatives thereof. They are usually 1 to 5% aqueous dispersions which are applied in thin layers of layer thickness between 20 and 200 nm, preferably between 40 and 150 nm, to the ITO substrate by spin coating, inkjet printing or other coating processes. Afterward, the PEDOT- or PANI-coated ITO substrates are dried. For the drying, several processes are possible. Conventionally, the films are dried in a drying oven between 110 and 200° C., preferably between 150 and 180° C., for from 1 to 10 minutes. However, newer drying processes, for example irradiation with IR (infrared) light, also lead to very good results, the irradiation time lasting only a few seconds. The low molecular weight materials used are preferably thin layers between 5 and 30 nm of copper-phthalocyanine (CuPc). Conventionally, CuPc is applied by vapor deposition in vacuum sublimation units at a pressure less than 10⁻⁵ mbar, preferably less than 10⁻⁶ mbar, more preferably less than 10⁻⁷ mbar. However, newer processes such as OPVD (Organic Physical Vapor Deposition) or LITI (Light-Induced Thermal Imaging) are also suitable for the coating of low molecular materials. All HILs have to not only inject holes very efficiently, but also adhere very securely to ITO and glass; this is the case both for CuPc and for PEDOT and PANI. A particularly low absorption in the visible range and thus a high transparency is exhibited by PEDOT and PANI, which is a further necessary property of the HIL.
3. One or more hole transport layers (Hole Transport Layer=HTL): in most OLEDs, one or more HTLs are a prerequisite for good efficiency and high stability. Very good results are achieved with a combination of two layers, for example consisting of triarylamines such as MTDATA (4,4′,4″-tris(N-3-methylphenyl)-N-phenylamino)triphenylamine) or NaphDATA (4,4′,4″-tris(N-1-naphthyl)-N-phenylamino)triphenylamine) as the first HTL and NPB (N,N′-di(naphth-1-yl)-N,N′-diphenylbenzidine) or spiro-TAD (tetrakis(2,2′,7,7′-diphenylamino)spiro-9,9′-bifluorene) as the second HTL. MTDATA or NaphDATA bring about an increase in the efficiency in most OLEDs by approx. 20-40%; owing to the higher glass transition temperature Tg, preference is given to NaphData (T_{g}=130° C.) over MTDATA (T_{g}=100° C.). As the second layer, preference is given to spiro-TAD (T_{g}=130° C.) over NPB (T_{g}=95° C.) owing to the higher T_{g}. In addition, better efficiencies are achieved for blue OLEDs with spiro-TAD. MTDATA and NaphDATA have a layer thickness between 5 and 100 nm, preferably 10 and 60 nm, more preferably between 15 and 40 nm. For thicker layers, somewhat higher voltages are required in order to achieve the same brightness; at the same time, the number of defects is reduced. spiro-TAD and NPB have a layer thickness between 5 and 150 nm, preferably 0.10 and 100 nm, more preferably between 20 and 60 nm. With increasing layer thickness of NPB and most other triarylamines, higher voltages are required for equal brightnesses. However, the layer thickness of spiro-TAD has only a slight influence on the characteristic current-voltage electroluminescence lines, i.e. the required voltage to achieve a particular brightness, depends only slightly upon the spiro-TAD layer thickness. All materials are applied by vapor deposition in vacuum sublimation units at a pressure of less than 10⁻⁵ mbar, preferably less than 10⁻⁶ mbar, more preferably less than 10⁻⁷ mbar. The vapor deposition rates may be between 0.01 and 10 nm/s, preferably 0.1 and 1 nm/s. For the HTL, the same applies as for the HIL; newer processes such as OPVD (Organic Physical Vapor Deposition) or LITI (Light-induced Thermal Imaging) are suitable for the coating of low molecular weight materials.
4. Emission layer (Emission Layer=EML): this layer may partly coincide with layers 3 and/or 5. It consists, for example, of a host material and at the same time fluorescent dyes such as spiro-DPVBi (2,2′,7,7′-tetrakis(2,2-diphenylvinyl)spiro-9,9′-bifluorene) and a hole transport material, for example spiro-TAD. Good results are achieved at a concentration of 5-10% spiro-TAD in spiro-DPVBi at an EML thickness of 15-70 nm, preferably 20-50 nm. All materials are applied by vapor deposition in vacuum sublimation units at a pressure of less than 10⁻⁵ mbar, preferably less than 10⁻⁶ mbar, more preferably less than 10⁻⁷ mbar. The vapor deposition rates may be between 0.01 and 10 nm/s, preferably 0.1 and 1 mm/s. For the EML, the same applies as for the HIL and HTL; relatively new processes such as OPVD or LITI are suitable for the coating of low molecular weight materials. For doped layers, OPVD has particularly great potential because the establishment of desired mixing ratios succeeds particularly efficiently. It is likewise possible to continuously change the concentration of the dopants. In the case of OPVD, the prerequisites for the improvement of the electroluminescent device are thus optimal.
5. An electron transport and hole blocking layer (Hole Blocking Layer=HBL): a very effective HBL material has been found to be particularly BCP (2,9-dimethyl-4,7-diphenyl-1,10-phenanthroline=bathocuproin). A thin layer of 3-20 nm, preferably 5-10 nm, increases the efficiency very effectively. All materials are applied by vapor deposition in vacuum sublimation units at a pressure of less than 10⁻⁵ mbar, preferably less than 10⁻⁶ mbar, more preferably less than 10⁻⁷ mbar. The vapor deposition rates may be between 0.01 and 10 nm/s, preferably 0.1 and 1 nm/s. OPVD is one further process for applying these materials to a substrate.
6. Electron transport layer (Electron Transport Layer=ETL): metal hydroxyquinolates are very suitable as ETL materials; particularly aluminum tris-8-hydroxyquinolate (AlQ₃) has been found to be one of the most stable electron conductors. All materials are applied by vapor deposition in vacuum sublimation units at a pressure of less than 10⁻⁵ mbar, preferably less than 10⁻⁶ mbar, more preferably less than 10⁻⁷ mbar. The vapor deposition rate may be between 0.01 and 10 nm/s, preferably 0.1 and 1 nm/s. For the EML, the same applies as for the HIL and HTL; relatively new processes such as OPVD or LITI are suitable for the coating of low molecular weight materials.
7. Electron injection layer (Electron Injection Layer=EIL): a thin layer having a layer thickness between 0.2 and 8 nm, preferably 0.5-5 nm, consisting of a material having a high dielectric constant, in particular inorganic fluorides and oxides, for example LiF, Li₂O, BaF₂, MgO, NaF and further materials, has been found to be particularly good as the EIL. Especially in combination with Al, this additional layer leads to a distinct improvement in the electron injection and thus to improved results with regard to lifetime, quantum efficiency and power efficiency. All materials are applied by vapor deposition in vacuum sublimation units at a pressure of less than 10⁻⁵ mbar, preferably less than 10⁻⁶ mbar, more preferably less than 10⁻⁷ mbar. The vapor deposition rates may be between 0.01 and 1 nm/s, preferably 0.1 and 0.5 nm/s.
8. Cathode: here, generally metals, metal combinations or metal alloys having a low work function are used, for example Ca, Ba, Cs, K, Na, Mg, Al, In, Mg/Ag. All materials are applied by vapor deposition in vacuum sublimation units at a pressure of less than 10⁻⁵ mbar, preferably less than 10⁻⁶ mbar, more preferably less than 10⁻⁷ mbar. The vapor deposition rates may be between 0.01 and 1 nm/s, preferably 0.1 and 0.5 nm/s.
9. Encapsulation: effective encapsulation of the organic layers including the EIL and the cathode is indispensable for organic electroluminescent devices. When the organic display is formed on a glass substrate, there are several options. One option is to adhesive-bond the entire structure to a second glass or metal plate. Two-component or UV-curing epoxy adhesives have been found to be particularly suitable. The electroluminescent device may be adhesive-bonded fully or else only at the edge. When the organic display is adhesive-bonded only at the edge, the durability can be additionally improved by adding what is known as a getter. This getter consists of a very hygroscopic material, especially metal oxides, for example BaO, CaO, etc., which binds ingressing water and water vapors. An additional binding of oxygen is achieved with getter materials, for example Ca, Ba, etc. In the case of flexible substrates, particular attention should be paid to a high diffusion barrier. Here, especially laminates composed of alternating thin plastics and inorganic layers (e.g. SiOₓ or SiNₓ) have been found to be useful.
10. Application spectrum: the structure described under points 1-9 is suitable both for monochrome and for full-color, passively or actively operated matrix displays for portable units, for example mobile telephones, PDAs, camcorders and other applications. In the case of passive-matrix displays, depending on the number of pixels, from 1000 to several hundred thousand cd/m² of peak brightness are required; first applications are between 5000 and 20 000 cd/m² of peak brightness. For full-color large-surface area high-resolution displays, preference is given to active-matrix control. The required brightness of the individual pixels is between 50 and 1000 cd/m², preferably between 100 and 300 cd/m². For this purpose too, the structure described under points 1-9 is suitable. Active-matrix control is suitable for all display applications (for example mobile telephones, PDAs and other applications), but particularly also for large-surface area applications, for example in laptops and televisions. Further applications are white or colored backlighting for monochromic or multicolor display elements (for example in pocket calculators, mobile telephones and other portable applications), large-surface area displays (for example traffic signs, billboards and other applications), or illumination elements in all colors and forms.

As described above, the production of the inventive devices may be carried out, apart from by sublimations processes or OPVD processes, also by specific printing processes (such as the LITI mentioned). This has advantages both with regard to the scaleability of the manufacturing and with regard to the establishment of mixing ratios in blend layers used. For this purpose, it is, though, generally necessary to prepare corresponding layers (for LITI: transfer layers) which are then transferred to the actual substrate.

These layers then comprise (in addition to any assistants needed, which are required for the transfer step) the mixture of hole conductor material and emitter material, as described above, in the desired ratio. These layers also form part of the subject matter of the present invention, as does the use of these layers to produce inventive devices.

The preparation of the inventive devices may also be carried out by other printing processes, for example the inkjet printing process.

The present application text and also the examples which follow below are directed only to organic light-emitting diodes and the corresponding displays. In spite of this restriction of the description, it is possible for those skilled in the art, without any further inventive activity, to produce and employ corresponding inventive layers, for example for organic solar cells (O-SCs), organic field-effect transistors (O-FETs) or else organic laser diodes (O-lasers), to name just a few further applications.

The present invention is illustrated in detail by the examples which follow without any intention that it be restricted thereto. Those skilled in the art can produce further inventive devices from the description and the adduced examples without inventive activity.

### EXAMPLES

The examples listed below had the following layer structure:

glass/ITO (80 nm)/HIL (60 nm)/HTL 1 (20 nm)/HTL 2 (20 nm)/EML (20-40 nm)/ETL (10-20 nm)/metal 1 (5 nm)/metal 2 (150 nm). Examples 10 and 11 additionally contained a blocking layer for holes (HBL) between EML and ETL. This resulted in the following layer structure for these examples: glass/ITO (80 nm)/HIL (60 nm)/HTL 1 (20 nm)/HTL 2 (20 nm)/EML (20-40 nm)/HBL (5-10 nm)/ETL (10-20 nm)/metal 1 (5-10 nm)/metal 2 (150 nm).
Glass coated with 80 nm of ITO was purchased from Merck-Balzers.
The HIL used was a 60 nm-thick PANI layer from Covion (Pat 010) or a 60 nm-thick PEDOT layer from Bayer (Baytron P 4083). The PANI layer was produced from a 4% dispersion by spin coating at 4000 rpm. The resulting layer was heated at 180° C. for five minutes. The PEDOT layer was produced from 2% dispersion by spin coating at 3000 rpm. The resulting layer was heated at 110° C. for five minutes.
The HTL 1 used was NaphDATA from Syntec. This material was purified by sublimation before use in OLEDs.
The HTL 2 used was spiro-TAD from Covion.
The EML is described more precisely in examples 1-13.
The HBL used was BCP from ABCR. This material was purified by sublimation before use in OLEDs.
The ETL used was AlQ₃ from Covion.
The metal 1 used was Ba from Aldrich.
The metal 2 used was Ag from Aldrich.

The organic materials (HTL 1/HTL 2/EMU(HBL)/ETL) were applied by vapor deposition one after the other in a vapor deposition apparatus from Pfeiffer-Vakuum, adapted by Covion, at a pressure of <10⁻⁶ mbar. The unit was equipped with an automatic rate and layer thickness control. The unmixed EML layers which were produced as a reference, just like HTL 1, HTL 2, ETL and HBL, were applied by vapor deposition in the Pfeiffer vapor deposition apparatus at a pressure of <10⁻⁶ mbar. In the case of the mixed EML layers (mixtures of two different materials), two materials were applied by vapor deposition simultaneously. The concentrations described in the examples were achieved by adjusting the rates according to the mixing ratios. The metals (metal 1/metal 2) were applied by vapor deposition in a vapor deposition apparatus from Balzers, adapted by Covion, at a pressure of <10⁻⁶ mbar. The unit was likewise equipped with an automatic rate and layer thickness control.

The substances, listed in the examples, of the mixtures are shown once more after the examples.

### Example 1

The layer structure corresponded to that described above: glass/ITO/PEDOT/NaphDATA/spiro-TAD/EML=spiro-DPVBi (+spiro-TAD)/AlQ₃/Ba/Ag. The two materials of the EML (the substances spiro-DPVBi+spiro-TAD) were developed and synthesized by Covion. The EML consisted of a mixture of the two substances (spiro-DPVBi+spiro-TAD), spiro-TAD having had a proportion of 10%. In addition, OLEDs were produced as a reference without the substance spiro-TAD in the EML. In the case of the mixture in the EML, the lifetime of the OLED increased by a factor of 3 in comparison to the reference OLED from approx. 1500 h to 4500 h. At the same time, the photometric efficiency (unit: cd/A) was improved by approx. 10% and the power efficiency was likewise increased. When a mixture of spiro-TAD and spiro-DPVBi with a concentration of 15% of spiro-DPVBi was prepared, the lifetime increased by a factor of 4 from approx. 1500 h to 6000 h. In addition, steeper characteristic I-U-EL lines were obtained, i.e. in order to achieve a certain brightness, lower voltages were required, for example only 4.5 V instead of 5.5 V for a brightness of 100 cd/m².

### Example 2

The layer structure corresponded to that described above: glass/ITO/PEDOT/NaphDATA/spiro-TAD/EML=spiro-DPVBi (+spiro-AA2)/AlQ₃/Ba/Ag. The two materials of the EML (the substances spiro-DPVBi and spiro-AA2) were developed and synthesized by Covion. The EML consisted of a mixture of the two substances (spiro-DPVBi and spiro-AA2), spiro-AA2 having had a proportion of 10%. In addition, OLEDs were produced as a reference without the substance spiro-AA2 in the EML. In the case of the mixture in the EML, the lifetime of the OLED was increased by a factor of >8 in comparison to the reference OLED from approx. 1500 h to >12 000 h. In addition, steeper characteristic I-U-EL lines were obtained, i.e. in order to achieve a certain brightness, lower voltages were required, for example only 4.5 V instead of 5.5 V for a brightness of 100 cd/m².

### Example 3

The layer structure corresponded to that described above: glass/ITO/PEDOT/NaphDATA/spiro-TAD/EML=spiro-Ant1 (+spiro-TAD)/AlQ₃/Ba/Ag. The two materials of the EML (the substances spiro-Ant1 and spiro-TAD) were developed and synthesized by Covion. The EML consisted of a mixture of the two substances (spiro-Ant1 and spiro-TAD), spiro-TAD having had a proportion of 50%. In addition, OLEDs were produced as a reference without the substance spiro-TAD in the EML. In the case of the mixture in the EML, the lifetime of the OLED was increased by a factor of >100 in comparison to the reference OLED from approx. 100 h to >10 000 h. In addition, steeper characteristic I-U-EL lines were obtained, i.e. in order to achieve a certain brightness, lower voltages were required, for example only 4.5 V instead of 6 V for a brightness of 100 cd/m².

### Example 4

The layer structure corresponded to that described above: glass/ITO/PEDOT/NaphDATA/spiro-TAD/EML=spiro-Ant2 (+spiro-TAD)/AlQ₃/Ba/Ag. The two materials of the EML (the substances spiro-Ant2 and spiro-TAD) were developed and synthesized by Covion. The EML consisted of a mixture of the two substances (spiro-Ant2 and spiro-TAD), spiro-TAD having had a proportion of 10%. In addition, OLEDs were produced as a reference without the substance spiro-TAD in the EML. In the case of the mixture in the EML, the lifetime of the OLED was increased by a factor of >3 in comparison to the reference OLED from approx. 300 h to >900 h. In addition, steeper characteristic I-U-EL lines were obtained, i.e. in order to achieve a certain brightness, lower voltages were required, for example only 5.5 V instead of 6.5 V for a brightness of 100 cd/m².

### Example 5

The layer structure corresponded to that described above: glass/ITO/PEDOT/NaphDATA/spiro-TAD/EML=spiro-pyrene (+spiro-TAD)/AlQ₃/Ba/Ag. The two materials of the EML (the substances spiro-pyrene and spiro-TAD) were developed and synthesized by Covion. The EML consisted of a mixture of the two substances (spiro-pyrene and spiro-TAD), spiro-TAD having had a proportion of 10%. In addition, OLEDs were produced as a reference without the substance spiro-TAD in the EML. In the case of the mixture in the EML, the lifetime of the OLED was increased by a factor of 3 in comparison to the reference OLED from approx. 1500 h to 4500 h. At the same time, the photometric efficiency (unit: cd/A) was improved by up to 20%, and the power efficiency was likewise increased. In addition, steeper characteristic I-U-EL lines were obtained, i.e. in order to achieve a certain brightness, lower voltages were required, for example only 4.5 V instead of 5.5 V for a brightness of 100 cd/m².

### Example 6

The layer structure corresponded to that described above: glass/ITO/PEDOT/NaphDATA/spiro-TAD/EML=TBPP (+spiro-TAD)/AlQ₃/Ba/Ag. The two materials of the EML (the substances TBPP and spiro-TAD) were developed and synthesized by Covion. The EML consisted of a mixture of the two substances (TBPP and spiro-TAD), spiro-TAD having had a proportion of 10%. In addition, OLEDs were produced as a reference without the substance spiro-TAD in the EML. In the case of the mixture in the EML, the lifetime of the OLED was increased by a factor of 10 in comparison to the reference OLED from approx. 500 h to 5000 h. At the same time, the photometric efficiency (unit: cd/A) was improved by up to 100%, and the power efficiency was likewise increased. In addition, steeper characteristic I-U-EL lines were obtained, i.e. in order to achieve a certain brightness, lower voltages were required, for example only 6 V instead of 7 V for a brightness of 100 cd/m².

### Example 7

The layer structure corresponded to that described above: glass/ITO/PEDOT/NaphDATA/spiro-TAD/EML=DTBTD (+spiro-TAD)/AlQ₃/Ba/Ag. The two materials of the EML (the substances DTBTD and spiro-TAD) were developed and synthesized by Covion. The EML consisted of a mixture of the two substances (DTBTD and spiro-TAD), spiro-TAD having had a proportion of 10%. In addition, OLEDs were produced as a reference without the substance spiro-TAD in the EML. In the case of the mixture in the EML, the lifetime of the OLED was increased by a factor of 8 in comparison to the reference OLED from approx. 500 h to 4000 h.

### Example 8

The layer structure corresponded to that described above: glass/ITO/PEDOT/NaphDATA/spiro-TAD/EML=BDPBTD (+spiro-TAD)/AlQ₃/Ba/Ag. The two materials of the EML (the substances BDPBTD and spiro-TAD) were developed and synthesized by Covion. The EML consisted of a mixture of the two substances (BDPBTD and spiro-TAD), spiro-TAD having had a proportion of 90%. In addition, OLEDs were produced as a reference without the substance spiro-TAD in the EML. In the case of the mixture in the EML, the lifetime of the OLED was increased by a factor of >10 in comparison to the reference OLED from approx. 1000 h to >10 000 h. At the same time, the photometric efficiency (unit: cd/A) was improved by up to 100%, and the power efficiency was likewise increased. In addition, steeper characteristic I-U-EL lines were obtained, i.e. in order to achieve a certain brightness, lower voltages were required, for example only 5 V instead of 8 V for a brightness of 100 cd/m².

### Example 9

The layer structure corresponded to that described above: glass/ITO/PEDOT/NaphDATA/spiro-TAD/EML=BDTBTD (+spiro-TAD)/AlQ₃/Ba/Ag. The two materials of the EML (the substances BDTBTD and spiro-TAD) were developed and synthesized by Covion. The EML consisted of a mixture of the two substances (BDTBTD and spiro-TAD), spiro-TAD having had a proportion of 90%. In addition, OLEDs were produced as a reference without the substance spiro-TAD in the EML. In the case of the mixture in the EML, the lifetime of the OLED was increased by a factor of 10 in comparison to the reference OLED from approx. 1000 h to 10 000 h. At the same time, the photometric efficiency (unit: cd/A) was improved by up to 400%, and the power efficiency was likewise increased. In addition, steeper characteristic I-U-EL lines were obtained, i.e. in order to achieve a certain brightness, lower voltages were required, for example only 6 V instead of 9 V for a brightness of 100 cd/m².

### Example 10

The layer structure corresponded to that described above with inclusion of the HBL: glass/ITO/PEDOT/NaphDATA/spiro-TAD/EML=IrPPy (+spiro-carbazole)/BCP/AlQ₃/Ba/Ag. IrPPy was synthesized by Covion, and spiro-Carbazole was developed and synthesized by Covion. The EML consisted of a mixture of the two substances (IrPPy and spiro-carbazole), spiro-carbazole having had a proportion of 90%. In addition, OLEDs were produced as a reference without the substance spiro-carbazole in the EML. The photometric efficiency (unit: cd/A) was improved by up to 500%, and the power efficiency was likewise increased. In addition, steeper characteristic I-U-EL lines were obtained, i.e. in order to achieve a certain brightness, lower voltages were required, for example only 6 V instead of 9 V for a brightness of 100 cd/m².

### Example 11

The layer structure corresponded to that described above with inclusion of the HBL: glass/ITO/PEDOT/NaphDATA/spiro-TAD/EML=IrPPy (+spiro-4PP6)/BCP/AlQ₃/Ba/Ag. IrPPy was synthesized by Covion, and spiro-4PP6 was developed and synthesized by Covion. The EML consisted of a mixture of the two substances (IrPPy and spiro-4PP6), spiro-4PP6 having had a proportion of 90%. In addition, OLEDs were produced as a reference without the substance spiro-4PP6 in the EML. The photometric efficiency (unit: cd/A) was improved by up to 400%, and the power efficiency was likewise increased. In addition, steeper characteristic I-U-EL lines were obtained, i.e. in order to achieve a certain brightness, lower voltages were required, for example only 5.5 V instead of 9 V for a brightness of 100 cd/m².

### Example 12

The layer structure corresponded to that described above: glass/ITO/PEDOT/NaphDATA/spiro-TAD/EML=spiro-Ant2 (+CPB)/AlQ₃/Ba/Ag. The two materials of the EML (the substances spiro-Ant2 and CPB) were developed and synthesized by Covion. The EML consisted of a mixture of the two substances (spiro-Ant2 and CPB), CPB having had a proportion of 20%. In addition, OLEDs were produced as a reference without the substance CPB in the EML. In the case of the mixture in the EML, the lifetime of the OLED was increased by a factor of 6 in comparison to the reference OLED from approx. 300 h to >1800 h. In addition, steeper characteristic I-U-EL lines were obtained, i.e. in order to achieve a certain brightness, lower voltages were required, for example only 6 V instead of 7 V for a brightness of 100 cd/m². In addition, the color coordinates improved: in the case of the reference OLED, CIE values of x=0.15 and y=0.15 were obtained; with a proportion of 20% CPB, x=0.15 and y=0.12 were achieved.

### Example 13

The layer structure corresponded to that described above: glass/ITO/PEDOT/NaphDATA/spiro-TAD/EML=spiro-pyrene (+CPB)/AlQ₃/Ba/Ag. CPB was synthesized by Covion, and spiro-pyrene was developed and synthesized by Covion. The EML consisted of a mixture of the two substances (spiro-pyrene and CPB), CPB having had a proportion of 10%. In addition, OLEDs were produced as a reference without the substance CPB in the EML. In the case of the mixture in the EML, the lifetime of the OLED was increased by a factor of 6 in comparison to the reference OLED from approx. 300 h to >1800 h. In addition, steeper characteristic I-U-EL lines were obtained, i.e. in order to achieve a certain brightness, lower voltages were required, for example only 6 V instead of 7 V for a brightness of 100 cd/m². In addition, the color coordinates improved: in the case of the reference OLED, CIE values of x=0.15 and y=0.20 were obtained; with a proportion of 10% CPB, x=0.15 and y=0.17 were achieved.

For better clarity, the substances mentioned in the examples adduced above are listed once more below:

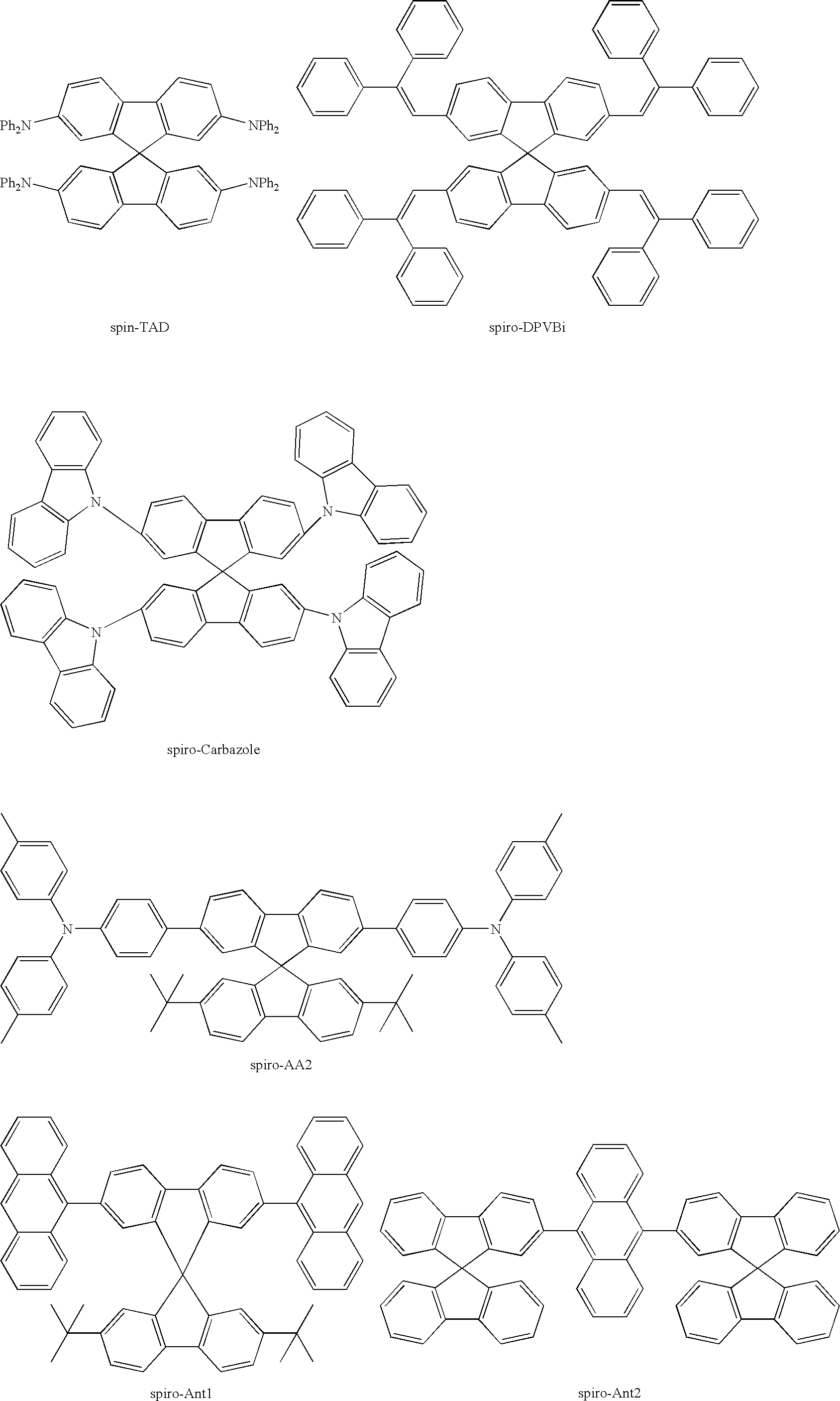

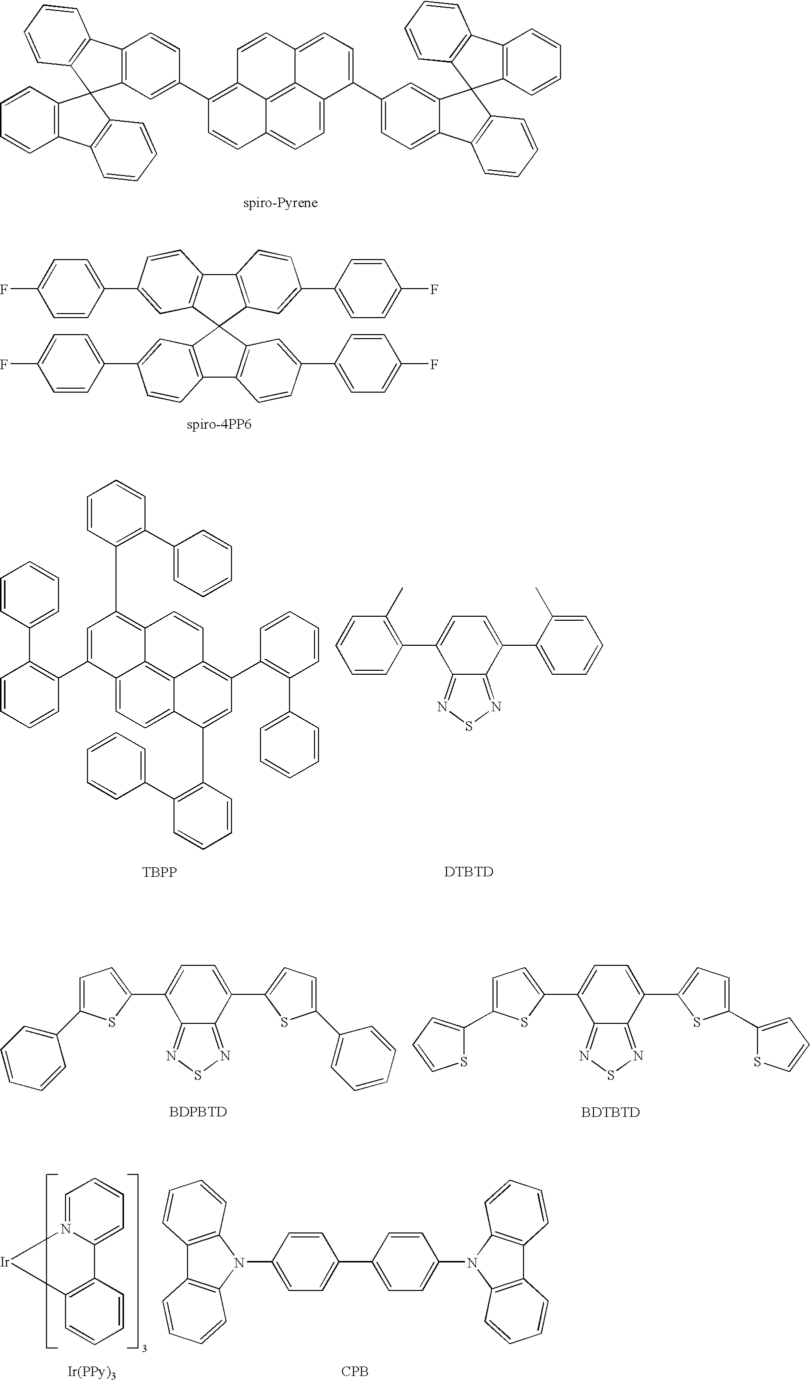

1. An organic electroluminescent device which has at least one emitting layer (EML) which comprises a mixture of at least one hole conductor material and at least one emission material capable of emission, characterized in that at least one of the two materials comprises one or more spiro-9,9′-bifluorene units and the weight ratio of hole conductor material to emission material is from 1:99 to 99:1.

2. The organic electroluminescent device as claimed in claim 1, characterized in that the emitting layer (EML) comprises a mixture of at least one hole conductor material and at least one emission material capable of emission, the HOMO of the hole conductor material lying in the range from 4.8 to 5.8 eV (vs. vacuum) and the compound having at least one substituted or unsubstituted diarylamino group, a triarylamino unit or a carbazole moiety, and the emission material capable of emission containing one or more spiro-9,9′-bifluorene units and the weight ratio of hole conductor material to emission material being from 1:99 to 99:1.

3. The organic electroluminescent device as claimed in claim 1, characterized in that the emitting layer (EML) comprises a mixture of at least one hole conductor material and at least one emission material capable of emission, the HOMO of the hole conductor material lying in the range from 4.8 to 5.8 eV (vs. vacuum) and the compound containing one or more spiro-9,9′-bifluorene units and at least one moiety selected from substituted or unsubstituted diarylamino, triarylamino, carbazole or thiophene units, and the emission material capable of emission is a metal complex stilbenamine, stilbenarylene, fused aromatic or heteroaromatic system, phosphorescent heavy metal complex, rhodamine, coumarin, substituted or unsubstituted hydroxyquinolinate of aluminum, zinc, gallium, bis(p-diarylaminostyryl)arylene, DPVBi (4,4′-bis(2,2-diphenylvinyl)biphenyl) anthracene, naphthacene, pentacene, pyrene, perylene, rubrene, quinacridone, benzothiadiazole compound. DCM (4-(dicyanomethylene)-2-methyl-6-(4-dimethylaminostyryl)-4H-pyran), DCJTB ([2-(1,1-dimethylethyl)-6-[2-(2,3,6,7-tetrahydro-1,1,7,7-tetramethyl-1H,5H-benzo[ij]quinolizin-9-yl)ethenyl]-4H-pyran-4-ylidene]propanedinitrile), complexes of iridium, europium or platinum, and the weight ratio of hole conductor material to emission material being from 1:99 to 99:1.

4. The organic electroluminescent device as claimed in claim 1, characterized in that the emitting layer (EML) comprises a mixture of at least one hole conductor material and at least one emission material capable of emission, the HOMO of the hole conductor material lying in the range from 4.8 to 5.8 eV (vs. vacuum) and the compound containing one or more spiro-9,9′-bifluorene units and at least one moiety selected from substituted or unsubstituted diarylamino, triarylamino, carbazole or thiophene units, and the emission material capable of emission comprising at least one spiro-9,9′-bifluorene unit and the weight ratio of hole conductor material to emission material being from 1:99 to 99:1.

5. The organic electroluminescent device as claimed in claim 1, characterized in that the weight ratio of hole conductor material to emission material is from 5:95 to 80:20.

6. The organic electroluminescent device as claimed in claim 1, characterized in that the weight ratio of hole conductor material to emission material is from 5:95 to 25:75.

7. The organic electroluminescent device as claimed in claim 1, characterized in that the glass transition temperature T_{g} of the hole conductor materials is greater than 90° C.

8. The organic electroluminescent device as claimed in claim 1, characterized in that the glass transition temperature T_{g} of the emission materials is greater than 100° C.

9. A compound of the formula (I) 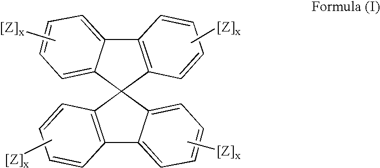
in which Z represents one or more groups of the formula 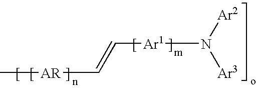
and in which the symbols and indices are:
AR, Ar¹, Ar² and Ar³ are the same or different at each instance and are each aromatic or heteroaromatic cycles which have from 4 to 40 carbon atoms and may be substituted with substituents R¹ at the free positions;
n is the same or different at each instance and is 0, 1 or 2;
m is the same or different at each instance and is 1 or 2;
o is the same or different at each instance and is 1, 2, 3, 4, 5 or 6; where AR on Ar² or on Ar³ or on both, may be bonded in the form of a dendrimer;
x is the same or different at each instance and is 0, 1, 2, 3 or 4, with the proviso that the sum of all indices x is unequal to zero,
R¹ is the same or different at each instance and is a straight-chain, branched or cyclic alkyl or alkoxy chain which has from 1 to 22 carbon atoms and in which one or more nonadjacent carbon atoms is optionally replaced by N—R², O, S, —CO—O—, O—CO-0, where one or more hydrogen atoms is optionally replaced by fluorine, an aryl or aryloxy group which has from 5 to 40 carbon atoms and in which one or more carbon atoms is optionally replaced by O, S or N and which is optionally substituted by one or more nonaromatic R¹ radicals, or Cl, F, CN, N(R²)₂, B(R²)₂, where two or more R¹ radicals may also form an aliphatic or aromatic, mono- or polycyclic ring system with one another;
R² is the same or different at each instance and is H, a straight-chain, branched or cyclic alkyl chain which has from 1 to 22 carbon atoms and in which one or more nonadjacent carbon atoms is optionally replaced by O, S, —CO—O—, O—CO—O, where one or more hydrogen atoms is optionally replaced by fluorine, an aryl group which has from 5 to 40 carbon atoms and in which one or more carbon atoms is optionally replaced by O, S or N and which is optionally substituted by one or more nonaromatic R¹ radicals.

10. A process for producing organic electroluminescent devices which comprises a hole conductor compound which comprises the compound as claimed in claim 9.

11. The organic electroluminescent device as claimed in claim 1, characterized in that one or more layers are produced by a sublimation process.

12. The organic electroluminescent device as claimed in in claim 1, characterized in that one or more layers are applied by the OPVD (organic physical vapor deposition) process.

13. The organic electroluminescent device as claimed in in claim 1, characterized in that one or more layers are applied by printing techniques.

14. The organic electroluminescent device as claimed in claim 13, characterized in that the printing technique is the inkjet process.

15. The organic electroluminescent device as claimed in claim 13, characterized in that the printing technique is the LITI process (light-induced thermal imaging).

16. An organic layer for the production of organic electroluminescent devices with the LITI process as claimed in claim 15, comprising at least one hole conductor material and at least one emission material capable of emission, characterized in that at least one of the two materials comprises one or more spiro-9,9′-bifluorene units and the weight ratio of hole conductor material to emission material is from 1:99 to 99:1.
